(19) United States
(12) Patent Application Publication
(10) Pub. No.: US 2009/0079082 A1
(43) Pub. Date: Mar. 26, 2009

(54) BONDING PAD STRUCTURE ALLOWING WIRE BONDING OVER AN ACTIVE AREA IN A SEMICONDUCTOR DIE AND METHOD OF MANUFACTURING SAME

(76) Inventors: Yong Liu, Scarborough, ME (US); Daniel Hahn, Cumberland, ME (US); Scott Irving, Cape Elizabeth, ME (US); Qi Wang, Sandy, UT (US)

Correspondence Address: HISCOCK & BARCLAY, LLP, 2000 HSBC PLAZA, 100 Chestnut Street, ROCHESTER, NY, 14604-2404, US

(21) Appl. No.: 11/860,217

(22) Filed: Sep. 24, 2007

(51) Int. Cl. H01L 23/488; H01L 21/44

(52) U.S. Cl. 257/773; 438/612; 257/E23.023; 257/E21.476

(57) ABSTRACT

A wire bonding pad over an active area of a semiconductor die has grooves in two orthogonal sections thereof in the top surface of said wire bonding pad.

### FIELD OF THE INVENTION

This invention relates to bonding pads over an active area (BPOA), and more particularly, to a BPOA with a blocked or waffle surface and with high density vias below the BPOA.

### BACKGROUND OF THE INVENTION

The common practice in the semiconductor industry is to place wire bonding pads outside of the active areas on semiconductor die since the stress which would be placed on the active areas during wire bonding has in the past sometimes damaged to some extent the active devices under the wire bond pads such that the resulting degradations of the reliability of the die and the device characteristics have not made the use of bonding pads over active areas (BPOA) feasible.

The use of bonding pads over active areas would, however, be highly advantageous since the die area required for the wire bonding pads is relatively large and consequently is a significant percentage of the die area.

### SUMMARY OF THE INVENTION

The invention comprises, in one form thereof, a wire bonding pad having grooves in two orthogonal sections thereof in the top surface of the wire bonding pad.

More particularly, the invention includes a wire bonding pad having grooves in two orthogonal sections thereof in the top surface of the wire bonding pad, located over an active area of a semiconductor die, and is directly connected to a lower conductive layer by one or more vias.

In another form, the invention includes a method of forming a wire bonding pad over an active region in a semiconductor die. The method comprises the steps of forming in a top dielectric layer one or more vias, forming a relatively hard metal region over a portion of the top dielectric layer and the via, forming a relatively soft metal region on top of the relatively hard metal region, and forming orthogonal grooves in the relatively soft metal region.

### BRIEF DESCRIPTION OF THE DRAWINGS

The aforementioned and other features, characteristics, advantages, and the invention in general will be better understood from the following more detailed description taken in conjunction with the accompanying drawings, in which:

FIGS. 1A, 1B, and 1C top plan diagrammatic views of various configurations for the location of wire bond pads and vias on a semiconductor die;

FIG. 2 is a side diagrammatic view of a portion of a semiconductor die having a bonding pad located over an active area (BPOA) according to an embodiment of the present invention;

FIGS. 3A, 3B, and 3C show the portion of the semiconductor die shown in FIG. 2 during selected steps in the fabrication of the semiconductor die;

FIG. 4 is a side diagrammatic view of a portion of a semiconductor die having a bonding pad located over an active area (BPOA) according to another embodiment of the present invention;

FIGS. 5A, 5B, 5C, 5D, and 5E show the portion of the semiconductor die shown in FIG. 4 during selected steps in the fabrication of the semiconductor die;

FIGS. 6A and 6B are top plan view mechanical drawings of two geometries which may be used with the bonding pads shown in FIGS. 2 and 4; and

FIGS. 7A and 7B are isometric top views of the bonding pads shown in FIGS. 6A and 6B, respectively.

It will be appreciated that for purposes of clarity and where deemed appropriate, reference numerals have been repeated in the figures to indicate corresponding features. Also, the relative size of various objects in the drawings has in some cases been distorted to more clearly show the invention.

### DETAILED DESCRIPTION

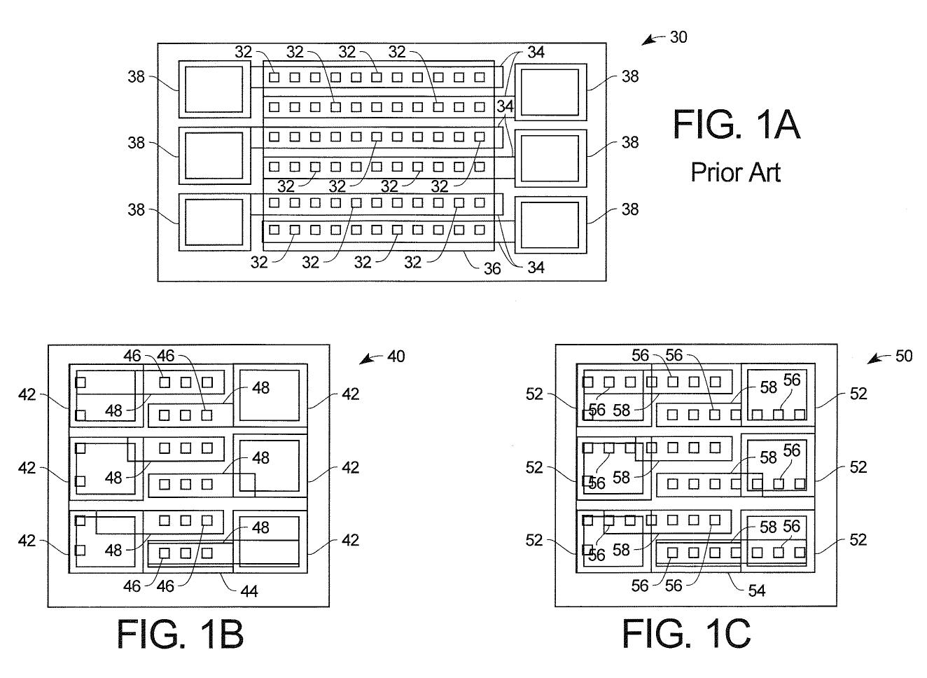

The advantage of having wire bonding pads over active areas is illustrated in the top diagrammatic view shown in FIGS. 1A, 1B, and 1C. FIG. 1A shows a semiconductor die 30 with vias 32 to metallization 34 over an active area 36 which connect to wire bonding pads 38 which are located outside the active area 36 which is common in the semiconductor industry. FIG. 1B shows another semiconductor die 40 which has wire bonding pads 42 located over the active area 44, but the vias 46 are outside the wire bonding pads 42 thus limiting the number of vias to the metallization 48. FIG. 1C shows a third semiconductor die 50 which has wire bonding pads 52 located over the active area 54, but with vias 56 located under the wire bonding pads 42 as well as over the rest of the active area 54 thus significantly increasing the number of vias 56 to the metallization 58 compared to the embodiment shown in FIG. 1B,

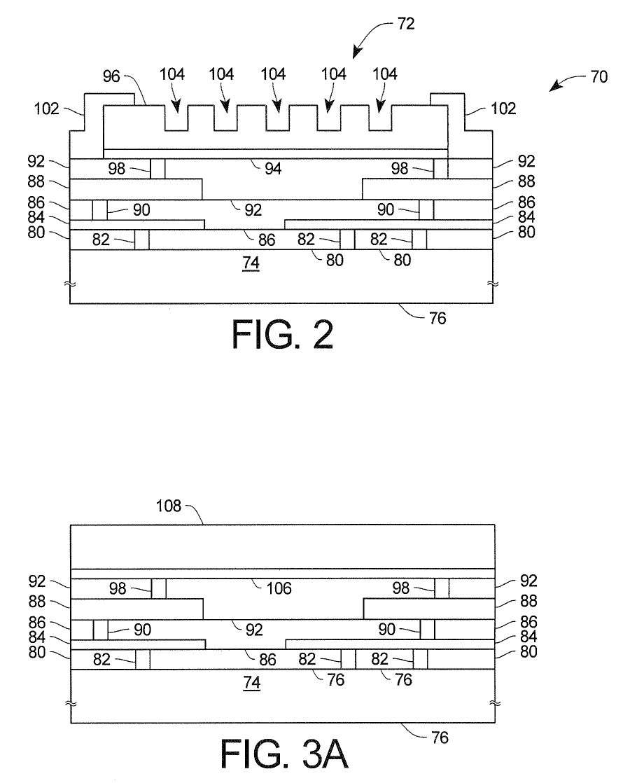

FIG. 2 is a diagrammatic view of a portion 70 of a semiconductor die having a bonding pad 72 located over an active area 74 (forming a BPOA) according to an embodiment of the present invention. The active area 74 is part of a semiconductor substrate 76 and has a first interlayer dielectric 80 on top of it with a plurality of plugs or contacts 82 extending from the active area 74 to a first metal layer 84. A second interlayer dielectric 86 separates the first metal layer 84 from a second metal layer 88 with a plurality of plugs or vias 90 located in the second interlayer dielectric layer 86 that electrically connect portions of the first and second metal layers together. A third interlayer dielectric 92 separates the second metal layer 88 from a TiW layer 94 which, in turn, separates the third interlayer dielectric 92 from a third metal layer 96. The TiW layer 94 and the third metal layer 96 form a BPOA 72. High density plugs or vias 98 connect the third metal layer 96 to the BPOA 72. A passivation layer 102 surrounds and extends over the edge of the TiW layer 94 and the third metal layer 96. The third metal layer 96 has a plurality of grooves 104 formed in the top of the third metal layer 96 which help to attenuate the forces applied to the BPOA 72 during a wire bonding operation on the BPOA 72 from the active area 74, and the intervening metal and interlayer dielectric layers.

In one or more embodiments of the present invention, the three interlayer dielectrics 80, 86, 92 are made of Tetraethyl Orthosilicate (TEOS), the first and second metal layers 84, 88 are AlCu (0.5%), the third metal layer 96 is AlCu (90.5%), the contacts 82 and the first and second interlayer vias 90, 98 are tungsten. In this embodiment the thicknesses of the respective layers and their ranges are the following:

| | | Nominal | |
|---|---|---|---|
| Layer, Contacts, & Vias | Ref No. | Thickness | Range |
| First Interlayer Dielectric | 80 | 0.8 μm | 0.2 μm-1.0 μm |
| Contacts | 82 | 0.8 μm | 0.2 μm-1.0 μm |
| First Metal Layer | 84 | 0.75 μm | 0.45 μm-1.2 μm |
| Second Interlayer Dielectric | 86 | 0.8 μm | 0.6 μm-1.2 μm |
| First Interlayer Vias | 90 | 0.8 μm | 0.6 μm-1.2 μm |
| Second Metal Layer | 88 | 1.2 μm | 0.55 μm-2.0 μm |
| Third Interlayer Dielectric | 92 | 3.0 μm | 1.5 μm-3.5 μm |
| Second Interlayer Vias | 98 | 3.0 μm | 1.5 μm-3.5 μm |
| TiW Layer | 94 | 0.3 μm | 0.1 μm-0.5 μm |
| Third Metal Layer | 96 | 2.4 μm | 2.0 μm-6.0 μm |

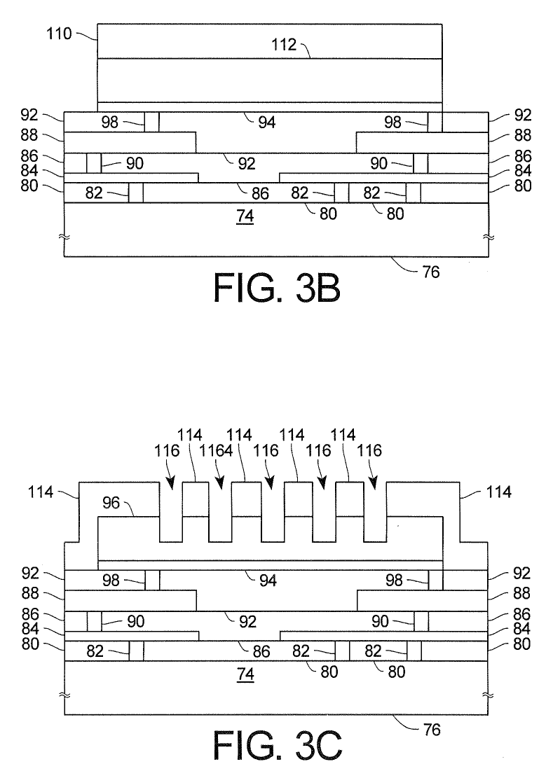

FIGS. 3A, 3B, and 3C show the portion 70 shown in FIG. 2 during selected steps in the fabrication of the semiconductor die. The interlayer dielectrics 80, 86, 92, the first and second metal layers 84, 88, the contacts 82, and the first and second interlayer vias 90, 98 are formed in a conventional manner well known in the art. In FIG. 3A TiW layer 106 is deposited on the semiconductor die, and a metallization layer 108 is deposited on the TiW 106. Turning to FIG. 3B, using photoresist 110 the TiW layer 94 and a metallization layer 112, which will become the third metallization layer 96, are formed. After the photoresist 110 is removed, a new coat of photoresist 114 is applied to the die and notches 116 are photo defined in the photoresist 114. The metallization layer 112 is etched using a timed etch to form the notches 104 which are about half the depth of the metallization layer 112, to form the third metallization layer 96 as shown in FIG. 3C. The photoresist 114 is removed and the die is passivated to form the structure shown in FIG. 2. In an alternative embodiment the passivation is formed before the metallization layer 112 is etched to form the notches 104.

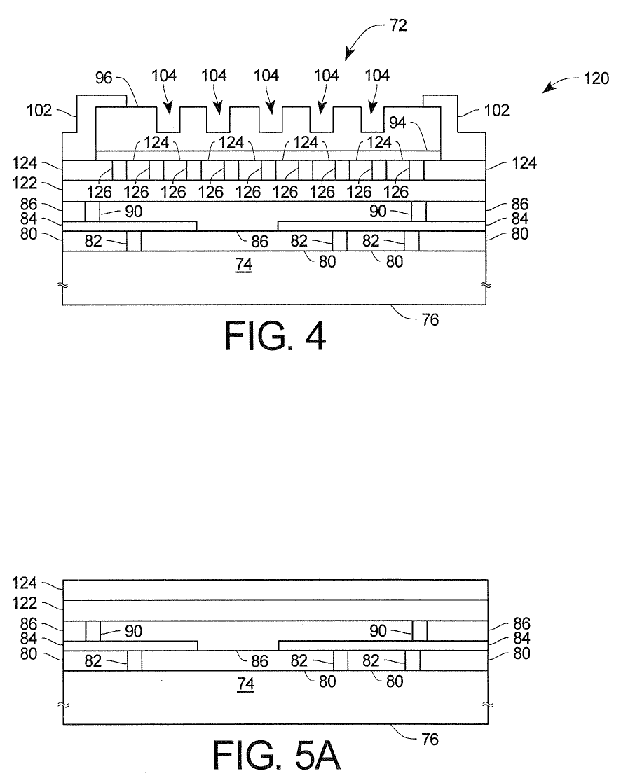

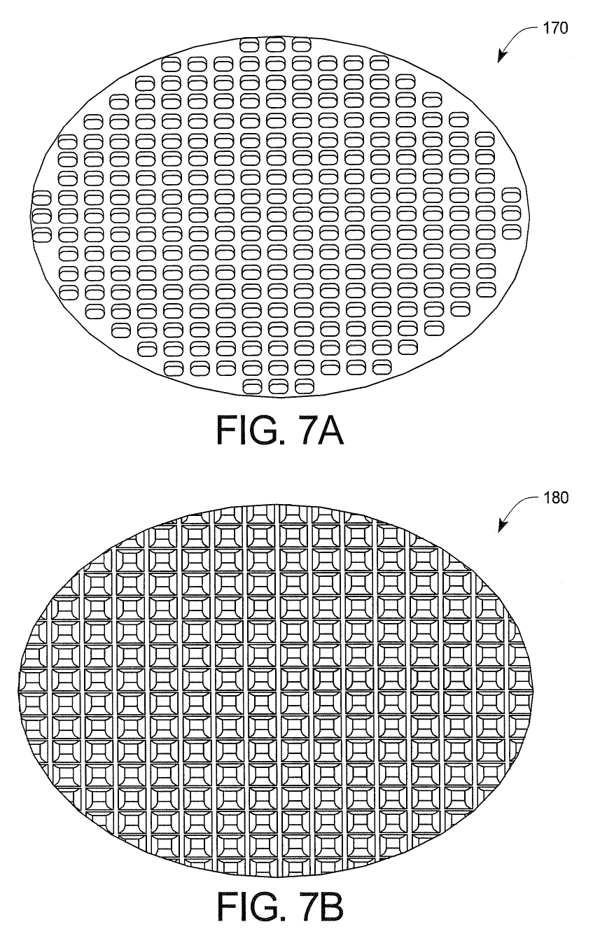

FIG. 4 is a side diagrammatic view of a portion 120 of a semiconductor die having a bonding pad 72 located over an active area according to another embodiment of the present invention. In the embodiment shown in FIG. 4 the number of vias 126 directly under the TiW layer 94 has been significantly increased as compared to the embodiment of FIG. 2. The number of vias 126 is significantly greater than the number of vias which would normally be used to connect the second metallization layer 112 to a third metallization layer like the second metallization layer 112. In order to more clearly show two embodiments of the present invention, FIGS. 2 and 4 show 5 grooves with one or more vias 126 under the bonding pad 72. However, the number of groves and vias is much greater as shown in the embodiments of FIGS. 7A and 7B. The actual number of grooves 104 will depend on the size of the wire bond pads. Similarly, the number and placement of the vias 126 in FIG. 4 will likewise depend on the size of the bonding pad and stress placed on the bonding pad during the formation of the wire bond. In test wafers, the stresses placed on the bonding pads 72 and the underlying layers and active devices have been found to be acceptable when a normal co-deformed wire bond was formed. Thus the testing indicates that special wire bonding procedures for the BPOAs 72 according to two or more embodiments of the present invention are not required.

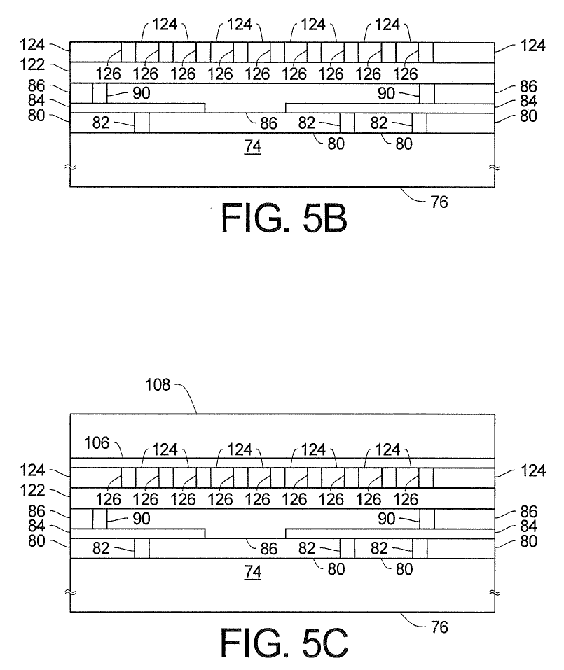

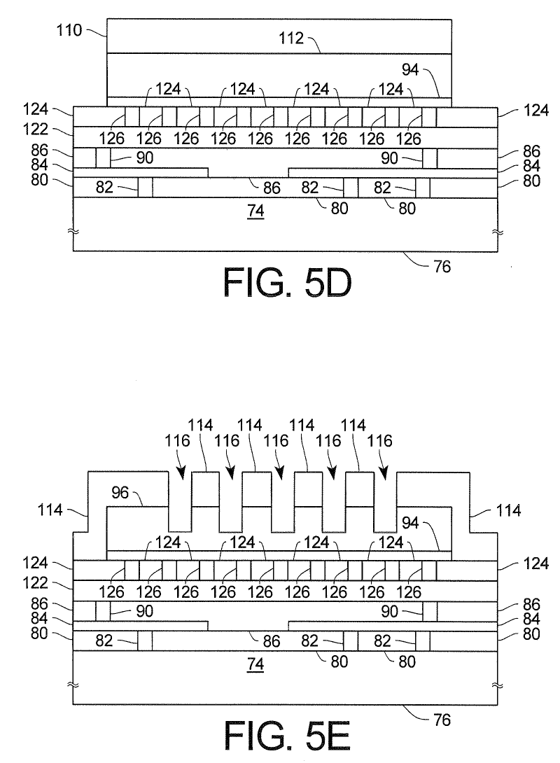

FIGS. 5A, 5B, 5C, 5D, and 5E show the portion of the semiconductor die shown in FIG. 4 during selected steps in the fabrication of the semiconductor die. As shown in FIG. 5A, interlayer dielectrics 80, 86, and 124, first and second metal layers 84 and 122, the contacts 82, and the first interlayer via 90, are formed in a conventional manner well known in the art. In FIG. 5B a plurality of vias 126 have been formed in the interlayer dialectic 124 in a region which will be below the BPOA 72. In FIG. 5C TiW layer 106 is deposited on the semiconductor die, and a metallization layer 108 is deposited on the TiW layer 106. Turning to FIG. 5D, using photoresist 110 the TiW layer 94 and a metallization layer 112, which will become the third metallization layer 96, are formed. After the photoresist 110 is removed, a new coat of photoresist 114 is applied to the die and notches 116 are photo defined in the photoresist 114 as shown in FIG. 5E. The metallization layer 112 is etched using a timed etch to form the notches 104 which are about half the depth of the metallization layer 112, to form the third metallization layer 96. The photoresist 114 is removed and the die is passivated to form the structure shown in FIG. 4.

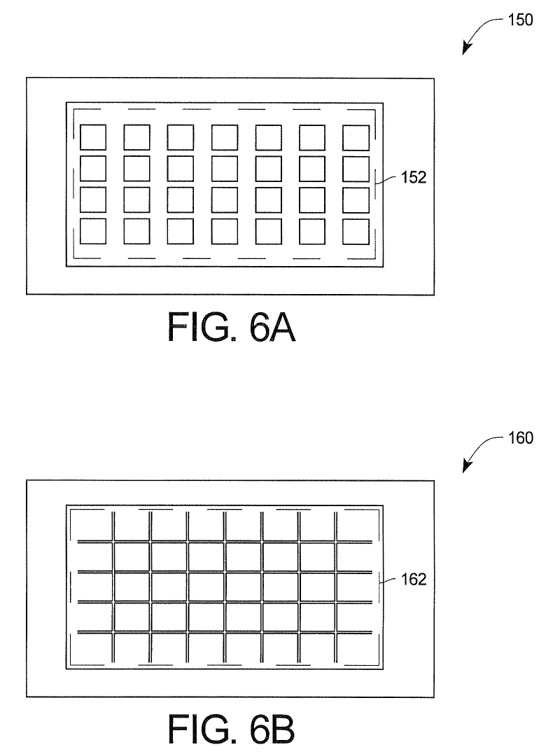

FIGS. 6A and 6B are top plan view mechanical drawings of two geometries 150 and 160, respectively, which may be used with the bonding pads shown in FIGS. 2 and 4. The grooves 104 shown in the drawings are the same for front and side views of the portions 70 and 120 of a semiconductor die, and the intersection of the two sets of orthogonal grooves can be formed as part of depressed blocks or islands 152 shown in FIG. 6A, or as crossing slots or grooves 162 shown in FIG. 6B.

Although FIGS. 2-6B show grooves 104 with vertical edges such as may be formed using anisotropic etching, the groves 104 may also have curved surfaces such as may be formed by wet etching.

FIGS. 7A and 7B are respective isometric top views 170 and 180 of the bonding pads shown in FIGS. 6A and 6B, respectively.

It is believed that one or more embodiments of a BPOA according to the present invention may help form good co-deformation between the free air ball (FAB) and the bond pad, and may also help avoid the FAB penetrating the bond pad.

It is also believed that the grooves 104 reduce the scrubbing of the bonding pads 72 during probe testing.

While the invention has been described with reference to particular embodiments, it will be understood by those skilled in the art that various changes may be made and equivalents may be substituted for elements thereof without departing from the scope of the invention. In addition, many modifications may be made to adapt a particular situation or material to the teachings of the invention without departing from the scope of the invention.

Therefore, it is intended that the invention not be limited to the particular embodiments disclosed as the best mode contemplated for carrying out this invention, but that the invention will include all embodiments falling within the scope and spirit of the appended claims.

1. A wire bonding pad having grooves in two orthogonal sections thereof in the top surface of said wire bonding pad.

2. The wire bonding pad of claim 1 wherein said wire bonding pad is located over an active area of a semiconductor die.

3. The wire bonding pad of claim 2 wherein said wire bonding pad is directly connected to a lower conductive layer of said semiconductor die by one or more vias.

4. The wire bonding pad of claim 3 wherein said wire bonding pad comprises a relatively soft metal with said grooves on a relatively hard metal.

5. The wire bonding pad of claim 4 wherein said relatively soft metal comprises aluminum and said relatively hard metal comprises tungsten.

6. The wire bonding pad of claim 3 wherein said grooves in said two orthogonal sections thereof form depressions in said wire bonding pad.

7. The wire bonding pad of claim 3 wherein said grooves in said two orthogonal sections thereof form islands in said wire bonding pad.

8. The wire bonding pad of claim 3 wherein the number of said one or more vias is significantly in excess of the number of vias which would be used to conduct current to a metal layer rather than to said wire bonding pad.

9. The wire bonding pad of claim 3 wherein said one or more vias is a high density via.

10. A wire bonding pad having grooves in two orthogonal sections thereof in the top surface of said wire bonding pad, located over an active area of a semiconductor die, and is directly connected to a lower conductive layer by one or more vias.

11. The wire bonding pad of claim 10 wherein said wire bonding pad comprises a relatively soft metal with said grooves on a relatively hard metal.

12. The wire bonding pad of claim 11 wherein said relatively soft metal comprises aluminum and said relatively hard metal comprises tungsten.

13. The wire bonding pad of claim 10 wherein said grooves in said two orthogonal sections thereof form depressions in said wire bonding pad.

14. The wire bonding pad of claim 10 wherein said grooves in said two orthogonal sections thereof form islands in said wire bonding pad.

15. The wire bonding pad of claim 10 wherein the number of said one or more vias is significantly in excess of the number of vias which would be used to conduct current to a metal layer rather than to said wire bonding pad.

16. The wire bonding pad of claim 10 wherein said one or more vias is a high density via.

17. A method of forming a wire bonding pad over an active region in a semiconductor die comprising the steps of:
a) forming in a top dielectric layer one or more vias;
b) forming a relatively hard metal region over a portion of said top dielectric layer and said one or more vias;
c) forming a relatively soft metal region on top of said relatively hard metal region; and
d) forming orthogonal grooves in said relatively soft metal region.

18. The method of claim 17 wherein said relatively soft metal region is formed from a metal comprising aluminum and said relatively hard metal region is formed from a metal comprising tungsten.

19. method of claim 17 wherein said orthogonal grooves form depressions in said wire bonding pad.

20. The method of claim 17 wherein said orthogonal grooves form islands in said wire bonding pad.

21. The method of claim 17 wherein the number of said one or more vias formed is significantly in excess of the number of vias which would be used to conduct current to a metal layer rather than to said wire bonding pad.

22. The wire bonding pad of claim 17 wherein said one or more vias is formed as a high density via.
